(19) United States
(12) Patent Application Publication
(10) Pub. No.: US 2007/0267719 A1
(43) Pub. Date: Nov. 22, 2007

(54) Structure and manufacturing method of high precision chip capacitor fabricated on silicon substrate

(76) Inventor: Jin Shown Shie, Hsinchu City (TW)

Correspondence Address: PERKINS COIE LLP, P.O. BOX 2168, MENLO PARK, CA, 94026, US

(21) Appl. No.: 11/437,074

(22) Filed: May 18, 2006

(51) Int. Cl. H01L 29/00

(52) U.S. Cl. 257/532; 257/E27.048

(57) ABSTRACT

The present invention provides a structure and the manufacturing method of high precision chip capacitor fabricated on silicon substrate. The structure of the chip capacitor consists of a dielectric layer formed on the surface of a heavily doped silicon substrate with an inner primary portion of thin oxide and an outer secondary portion of thicker oxide; both oxides are merged seamlessly together into the single dielectric layer thus allowing a layer of electrically conducting film deposited on its surface as the first electrode of the capacitor, while the heavily doped silicon substrate on the opposite surface of the dielectric oxide plays as the bottom electrode. The bottom electrode is electrically connected up to a second electrode on the upper surface through a via so that both the first and second electrodes can be on the same surface for subsequent bumping process, finally, two solder bumps is formed on the top as a surface mountable chip capacitor component.

### BACKGROUND OF THE INVENTION

1. Field of the invention

The present invention relates to a chip capacitor. In particular, the present invention relates to a structure and manufacturing method of high precision chip capacitor fabricated on silicon substrate.

2. Description of the Related Art

Modern surface mount chip capacitor is widely used in electronic circuit board. There are a variety of well-known manufacturing methods of chip capacitor. One of the newest methods of fabrication is the capacitor by electro-plating a layer of conductive powder element on a foil to be the substrate anode, and after sintering, a thin dielectric film is formed over the conductive powder by placing in an oxygen-forming solution, finally, a cathode is formed on top. This technology is described in U.S. Pat. No. 6/914,770, to Goldberger et al. The process is not at all compatible with the silicon integrated circuit foundry, and its accuracy is not easy to control.

The technology described in U.S. Pat. No. 6,700,771 and U.S. Pat. No. 6,955,960, to Bhattacharyya is an on-chip capacitor in which a high K dielectric layer doped with nano crystals deposited on a substrate and a top plate layer disposed on the high K dielectric layer to form an MIS (Metal-lnsulator-Silicon) or MIM (Metal-Insulator-Metal) capacitor. The high K dielectric layer includes material such as Al₂O₃. Both of these capacitors are fabricated together with the IC circuit to be the decoupling capacitor for a circuit to reduce the resonance impedance. They are not suitable with surface mount technology.

Therefore there is a need to develop a fabrication technology of a chip-capacitor on a silicon substrate (on chip-capacitor) using silicon dioxide (SiO₂) thin film as the dielectric layer,.and having highly accurate capacitance value.

### OBJECTS OF THE INVENTION

It is therefore an object of the present invention to provide a chip capacitor used silicon substrate such that the capacitor can be fabricated by the standard IC and bump foundries to reduce the fabrication cost.

It is another object of the invention to provide a chip capacitor using a thick field oxide and a thin oxide as the insulation layer to reduce the capacitance error due to the edge variation caused by etching of the electrode pattern.

It is yet another object of the invention to provide a chip capacitor using lithographic method to define the scribe line and the pattern of the positive metal electrode to give an accurate positive electrode area so that the predefined capacitance will be the same from chip to chip.

It is yet another object of the invention to provide a chip capacitor trimming the upper electrode at the thick oxide region where the rule of trimming is loser in comparison with trimming at the thin oxide region.

### DISCLOSURE OF THE INVENTION

A first aspect of the present invention teaches a structure of precision chip capacitor fabricated on silicon substrate, including: a heavily doped silicon substrate; a secondary thick oxide region, formed on the silicon substrate around a predefined central region; a main thin oxide region, formed on the predefined central region to be the dielectric layer of the capacitor; a first electrode, patterned to cover over entire the thin oxide region and part of the thick oxide region acts as one capacitor electrode; the first electrode is ablative trimming on the thick oxide area to obtain better precision capacitance; a first solder bump, formed on the first electrode; a second solder bump, formed on the second electrode; and a second electrode, part on top of the thick oxide patterned to connect to the silicon substrate below the thin oxide layer and the thick oxide layer through via to be the other electrode of the capacitor.

Another preferred embodiment of the present invention teaches a method of manufacturing precision chip capacitor fabricated on silicon substrate, including the following steps: a heavily doped silicon wafer used as the substrate; a pad-oxide/nitride layer with area of L₁×L₁ grown and deposited on the substrate, by lithography and etching using a first mask to define the thin oxide area which also defines the area of the capacitor; a secondary thick oxide grown by wet oxidation around the pad-oxide/nitride layer to a thickness of D₂, then removing the pad-oxide/nitride layer; a main thin oxide layer grown by dry oxidation on the substrate to be the dielectric layer of the capacitor to a thickness of D₁; a contact via hole opened on one side of the secondary thick oxide of each capacitor by lithography and etching using a second mask; an electrical conductive film deposited on the surface of the substrate and filling the contact via hole; the electrical conductive film patterned to form scribe lines around each capacitor and metal patterning on each capacitor; electroplating of a first solder bump on the first electrode and a second solder bump on the second electrode; Finally, ablative trimming the electrode metal of the first electrode on the secondary thick oxide to give a precision capacitance value.

In one preferred embodiment, the doping of the silicon substrate is between 10¹⁸ atom/cm³ to 10²¹ atom/cm³, the thickness of said secondary thick oxide is between 500 nm to 1000 nm and the thickness of the main thin oxide is between 10 nm to 200 nm.

### BRIEF DESCRIPTION OF THE DRAWINGS

The foregoing and other advantages of the invention will be fully understood with reference to the description of the best embodiment and the drawing wherein:

FIG. 1 is the cross sectional view of the process steps in according to one embodiment of the present invention.

FIG. 2 is a top view of one chip of the silicon wafer in according to one embodiment of the present invention.

### DESCRIPTION OF THE PREFERRED EMBODIMENTS

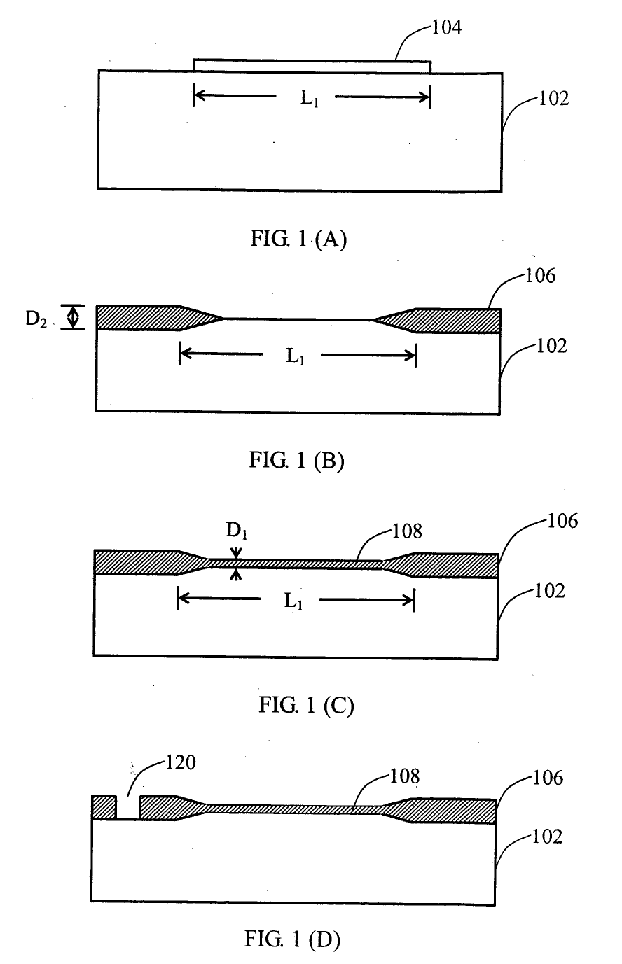

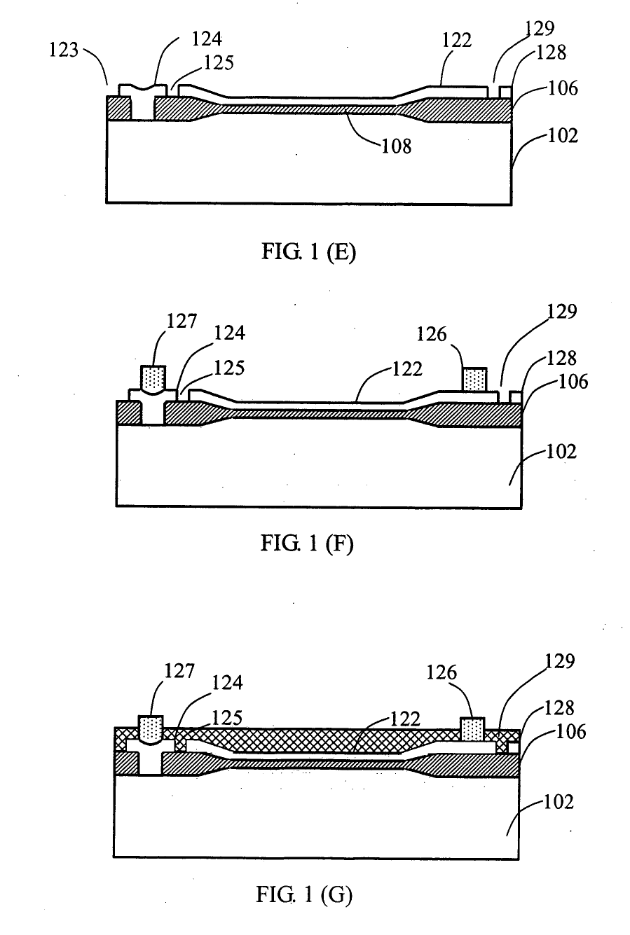

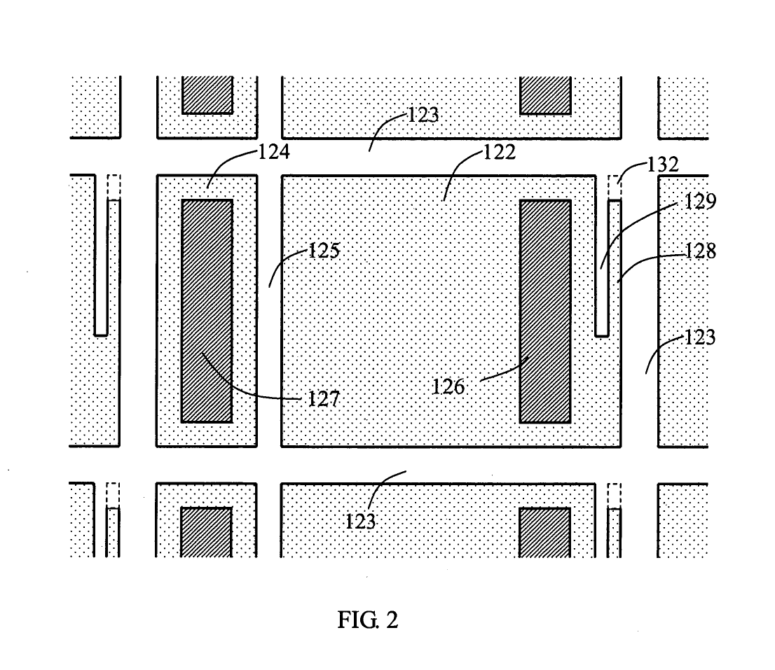

One embodiment of a chip capacitor for flip-chip bounding of the present invention consists of at least a dielectric layer, a first electrode, a second electrode, a first bumping and a second bumping. FIG. 1 is the cross sectional view of the process steps in according to one embodiment of the present invention. In the first step, as shown in FIG. 1 (A), the process begins with a P-type or an N-type heavily doped silicon wafer as the substrate 102, the doping of the silicon substrate is between 10¹⁸ atom/cm³ to 10²¹ atom/cm³. A pad-oxide/nitride layer 104 with length L₁ is grown and deposited on the substrate 102, by lithography and etching using a first mask to define the thin oxide area which also defines the area of the capacitor. This process is used in conventional process to define the active area of the integrated circuit. In the second step, as shown in FIG. 1 (B), a secondary thick oxide 106 is grown by wet oxidation around the pad-oxide/nitride layer 104, the thickness D₂ of the secondary thick oxide 106 is between 500 nm to 1000 nm. Then remove the pad-oxide/nitride layer 104 to expose the silicon surface of the inner primary portion of the chip. In step 3, as shown in FIG. 1 (C), a main thin oxide 108 is grown by dry oxidation on the substrate to be the dielectric layer of the capacitor, like those gate oxide in conventional IC process. The thickness D₁ of the main thin oxide 108 is between 10 nm to 200 nm depends on the voltage range and the capacitance range of the capacitor. In step 4, as shown in FIG. 1 (D), a contact via hole 120 is opened on one side of the secondary thick oxide and scribe lines 123 (see FIG. 2) are formed by lithography and etching. In step 5, as shown in FIG. 1 (E), an electrical conductive film is deposited on the surface of the substrate and filling the via hole, then metal patterning 125, 128 and scribe lines 123 (see FIG. 2) are carried out with lithography and etching method to form a first electrode 122, a second electrode 124 and a trimming bar 128 by removing the metal and exposed the secondary thick oxide 106, the scribe line is used for scribing the wafer to form separated chips. This process provides an advantage of reducing the capacitance error due to the edge variation caused by etching of the electrode pattern because the variation is on the thick oxide, it also gives an accurate area of the first electrode122. Then the capacitance of each chip can be measured and ablative trim out part of the trimming bar 128 on the thick oxide 106 a small trimming area 132 (see FIG. 2) to give the require capacitance, the accuracy of the capacitance can be improved by trimming the trimming bar 128 on the thick oxide region 106 and removing the trimming area 132 where the rule of trimming is loser in comparison with trimming at the thin oxide region 108. Finally, in step 6, as shown in FIG. 1 (F), the substrate is taken out from the IC foundry and transferred to a foundry for electroplating of the first solder bump 126 on the first electrode 122 and the second solder bump 127 on the second electrode 124, then the substrate is taken back to the IC foundry for ablative trimming a small trimming area 132 of the trimming bar 128 on the secondary thick oxide 106 to give a precision capacitance value, because the ablative trimming is made on the thick oxide area, this gives less capacitance change in comparison with trimming on the thin oxide area, therefore better precision of the capacitance can be obtained. Refer to FIG. 2, FIG. 2 is a top view of one chip of the silicon wafer in according to one embodiment of the present invention. It can be seen that the first electrode 122 and the second electrode 124 are separated by a metal patterning 125, scribe lines 123 are formed around each capacitor. We can also see the first bumping 126, the second bumping 127 and the trimming bar 128.

Analysis of the manufacturing accuracy of the chip capacitor of the present invention can be described as follow: wherein,
d_{P} is the primary dielectric thickness; thin oxide ˜50 nm with the dielectric strength ˜10⁷ V/cm.
Hence: the breakdown voltage is resistible up to 10⁷ V/cm×50 nm˜50 volts.

This value is higher than the widely used specification of breakdown voltage of chip capacitors, which is 6/10/16/25 volts.

The capacitance C is given by the formula:

$$C = ∈ \frac{A}{D}$$

With a practical capacitance of C=10 pf and the oxide thickness D=50 nm, the chip area A ˜120 um×120 μm which is small enough. Even for a larger 40 pf capacitor in the current commercial market, the area is increased to only 200 μm×200 μm with the same breakdown voltage of 50 volts. The size is small enough for 0201 SMD package which has a dimension of 300×600 micron square. Therefore if the area is further enlarged the oxide thickness can be also increased proportionally, which not only upgrades the breakdown voltage, but also improves the thickness accuracy of the grown native oxide hence the precision the fabricated capacitance.

Further accuracy analysis using the following definitions and constraints:
A_{P}: Primary electrode area; A_{S}: Secondary electrode area;
d_{S}: Secondary dielectric thickness of field oxide˜1000 nm;
Δᵢ: Inner area offset between primary and secondary capacitors;
Δₒ: Outer area offset on secondary capacitor;
d_{P}: Thickness offset of primary oxide;
d_{S}: Thickness offset of secondary oxide.

### Conditions:

d_{S}>>d_{P}; 2. A_{P}>A_{S}>Δᵢ+Δₒ 1.

### The total capacitance is breakdown into two parts as the primary capacitance Cₚ and the secondary capacitance Cₛ:

$$C = {C}_{P} + {C}_{S} = ∈ \frac{{A}_{P}}{{D}_{P}} + ∈ \frac{{A}_{S}}{{D}_{S}} .$$

### Therefore the capacitance error

$${δ}_{C} = ∈ \frac{1}{{D}_{P}} δ {A}_{P} - ∈ \frac{{A}_{P}}{{D}_{P}^{2}} δ {D}_{P} + ∈ \frac{1}{{D}_{S}} δ {A}_{S} - ∈ \frac{{A}_{S}}{{D}_{S}^{2}} δ {D}_{S}$$

### Since the upper electrode covers on both primary and secondary areas, the errors of the two areas are mutually correlated by

δ A_{P}=Δᵢ and δ A_{S}=−Δᵢ+Δₒ.

However the thicknesses δD_{P} and δD_{S} are independent. Hence

$${δ}_{C} = ∈ \frac{1}{{D}_{P}} {Δ}_{i} - ∈ \frac{1}{{D}_{S}} {Δ}_{i} + ∈ \frac{1}{{D}_{S}} {Δ}_{o} - ∈ \frac{{A}_{P}}{{D}_{P}^{2}} δ {D}_{P} - ∈ \frac{{A}_{S}}{{D}_{S}^{2}} δ {D}_{S}$$

And the offset percentage on total capacitance:

$$\begin{matrix}\frac{{δ}_{C}}{C} \times 100 \% = \frac{\{ ( \frac{1}{{D}_{P}} - \frac{1}{{D}_{S}} ) {Δ}_{i} + \frac{1}{{D}_{S}} {Δ}_{o} - \frac{{A}_{P}}{{D}_{P}^{2}} δ {D}_{P} - \frac{{A}_{S}}{{D}_{S}^{2}} δ {D}_{S} \}}{\frac{{A}_{P}}{{D}_{P}} + \frac{{A}_{S}}{{D}_{S}}} \\ = \frac{{D}_{P} \{ ( \frac{1}{{D}_{P}} - \frac{1}{{D}_{S}} ) {Δ}_{i} + \frac{1}{{D}_{S}} {Δ}_{o} - \frac{{A}_{P}}{{D}_{P}^{2}} δ {D}_{P} - \frac{{A}_{S}}{{D}_{S}^{2}} δ {D}_{S} \}}{{A}_{P} ( 1 + \frac{{A}_{S}}{{A}_{P}} \cdot \frac{{D}_{P}}{{D}_{S}} )} \\ = \frac{1}{( 1 + \frac{{A}_{S}}{{A}_{P}} \cdot \frac{{D}_{P}}{{D}_{S}} )} \\ [ ( 1 - \frac{{D}_{P}}{{D}_{S}} ) \frac{{Δ}_{i}}{{A}_{P}} + \frac{{D}_{P}}{{D}_{S}} \cdot \frac{{Δ}_{o}}{{A}_{P}} - \frac{δ {D}_{P}}{{D}_{P}} - \frac{{A}_{S}}{{A}_{P}} \cdot \frac{{D}_{P}}{{D}_{S}} \cdot \frac{δ {D}_{S}}{{D}_{S}} ]\end{matrix}$$

### Where,

(D_{S}−D_{P})Δᵢ=Inner offset at primary and secondary boundary;
Δₒ=Outer offset at secondary metal boundary;
A_{P}D_{S}δ D_{P}=Primary thickness offset;
A_{S}D_{P}δ D_{S}=Secondary thickness offset;

### The capacitance error can be traced to each error term as expressed by the following equation 1:

$$\frac{{δ}_{C}}{C} = \frac{1}{( 1 + \frac{{A}_{S}}{{A}_{P}} \cdot \frac{{D}_{P}}{{D}_{S}} )} [ ( 1 - \frac{{D}_{P}}{{D}_{S}} ) \frac{{Δ}_{i}}{{A}_{P}} + \frac{{D}_{P}}{{D}_{S}} \cdot \frac{{Δ}_{o}}{{A}_{P}} - \frac{δ {D}_{P}}{{D}_{P}} [ 1 + \frac{{A}_{S}}{{A}_{P}} \cdot \frac{{D}_{P}}{{D}_{S}} \cdot \frac{( \frac{δ {D}_{S}}{{D}_{S}} )}{( \frac{δ {D}_{P}}{{D}_{P}} )} ] \qquad eq . 1$$

With practical assumptions:
D_{P}˜1000 nm, D_{S}˜50 nm, D_{P}/D_{S}˜1/20<<1, and A_{S}<A_{P}, we have

A_{S}/A_{P}·D_{P}/D_{S}<1/20

Also, the degree of thin oxide offset, δ D_{P}/D_{P}, is surly larger than that of thicker field oxide, δ D_{S}/D_{S}, that is

|δ D_{S}/D_{S}|<|δ D_{P}/D_{P}|.

This is due to parabolic growth rate of native thermal oxide, which is slower for thick oxide than thin oxide and is easier to control by growth time. Hence by conservative estimation,

$$\frac{{δ}_{C}}{C} ≅ \frac{{Δ}_{i}}{{A}_{P}} + \frac{{D}_{P}}{{D}_{S}} ( 1 - \frac{{Δ}_{i}}{{Δ}_{O}} ) \cdot \frac{{Δ}_{o}}{{A}_{P}} - \frac{δ {D}_{P}}{{D}_{P}}$$

, omitting the factor

$$( 1 + \frac{{A}_{S}}{{A}_{P}} \cdot \frac{{D}_{P}}{{D}_{S}} ) ≅ 1$$

in the denominator of equ. 1. Therefore careful process control to have both δ D_{P}/D_{P} and Δᵢ/A_{P}<0.05% is most important to produce accurate capacitor if trimming of the capacitor is to be exempted. The capacitance error without trimming is expressed by

$$\frac{{δ}_{C}}{C} ≅ \frac{{Δ}_{i}}{{A}_{P}} - \frac{δ {D}_{P}}{{D}_{P}} .$$

### The outer secondary capacitance offset, Δo, is negligible due to the factor of thickness ratio, D_{S}/D_{P}˜20, and the comparable offset values, Δₒ˜Δᵢ.

Assume: A_{P}=150 μm×150 μm; dᵢ=0.25 μm,

$$\frac{{Δ}_{i}}{{A}_{P}} = \vert \frac{{( 150 \pm 0.25 )}^{2} - {150}^{2}}{{150}^{2}} \vert ≅ \vert \frac{2 \times 0.25 \times 150}{{150}^{2}} \vert ≅ \frac{1}{300} ≅ 0.34 \%$$

with D_{P}=150 nm and δD_{P}=1.2 nm, we have

$$\frac{δ {D}_{P}}{{D}_{P}} = \frac{1.2}{150} ∼ 0.8 \%$$

which means,

$$\frac{{δ}_{C}}{C} ≅ \frac{{Δ}_{i}}{{A}_{P}} + \frac{δ {D}_{P}}{{D}_{P}} ≅ \sqrt{{0.8}^{2} + {0.34}^{2}} \% = \sqrt{0.7556} \% ≅ 0.87 \% < 1 \%$$

Under this condition, trimming on the as made capacitor is not necessary for within 1% accuracy. However, if it is still required for even better accuracy, trimming the capacitor on the thicker field oxide region will be an order less tight compared to that trimming on the thinner thin oxide area because of the smaller capacitance variation on the thicker field oxide. In another word, the present two thickness structure of the capacitor oxide makes it very useful for accurate capacitor fabrication.

Another advantage of the structure is that it can be fabricated totally by the standard MOS process, namely, field oxide, thin oxide, body contact, and the general aluminum metallization or other metals permissible by the foundry. Therefore heavy investment is exempted while have best process for producing precision chip capacitors on silicon wafer, in comparison with the conventional screen process on alumina substrate.

Although specific embodiments of the invention have been disclosed, it will be understood by those having skill in the art that minor changes can be made to the form and details of the specific embodiments disclosed herein, without departing from the scope of the invention. The embodiments presented above are for purposes of example only and are not to be taken to limit the scope of the appended claims.

What is claimed is:

1. A structure of precision chip capacitor fabricated on silicon substrate, comprising:
A heavily doped silicon substrate;
A secondary thick oxide region, formed on said silicon substrate around a predefined inner region;
A main thin oxide region, formed on said predefined inner region to be the dielectric layer of the capacitor;
A first electrode, is patterned to cover over entire said thin oxide region and part of said thick oxide region acts as one capacitor electrode; said first electrode is ablative trimmed on said thick oxide area, if necessary, to obtain extremely high precision capacitance;
A first solder bump, formed on said first electrode;
A second electrode, on top of said thick oxide layer is patterned to connect said silicon substrate below said thin oxide layer and thick oxide layer through via to be the other electrode of said capacitor;
A second solder bump formed on said second electrode.

2. A structure of precision chip capacitor as recited in claim 1, wherein the doping of said silicon substrate is between 10¹⁸ atom/cm³ to 10²¹ atom/cm³.

3. A structure of precision chip capacitor as recited in claim 1, wherein the thickness of said secondary thick oxide is between 500 nm to 1000 nm.

4. A structure of precision chip capacitor as recited in claim 1, wherein the thickness of said main thin oxide is between 10 nm to 300 nm.

5. A method of manufacturing precision chip capacitor fabricated on silicon substrate, comprising the following steps:
A heavily doped silicon wafer is used as the substrate;
A pad-oxide/nitride layer with area of L₁×L₁ is grown and deposited on said substrate, by lithography and etching using a first mask to define the thin oxide area which also defines the area of the capacitor;
A secondary thick oxide layer is grown by wet oxidation around said pad-oxide/nitride layer to a thickness of D₂, then remove said pad-oxide/nitride layer;
A main thin oxide layer is grown by dry oxidation on said substrate to be the dielectric layer of the capacitor to a thickness of D₁;
A contact via hole is opened on one side of said secondary thick oxide layer of each capacitor by lithography and etching with a second mask;
An electrical conductive film is deposited on the surface of said substrate and filling said contact via hole;
Said electrical conductive film is patterned to form scribe-lines around each capacitor and metal patterning on each capacitor to form a first electrode with a trimming bar and a second electrode;
Electroplating of a first solder bump on said first electrode and a second solder bump on said second electrode;
Ablative trimming said trimming bar of said first electrode on said secondary thick oxide to give a precision capacitance value.

6. A method of manufacturing precision chip capacitor as recited in claim 5, wherein the doping of said silicon substrate is between 10¹⁸ atom/cm³ to 10²¹ atom/cm³.

7. A method of manufacturing precision chip capacitor as recited in claim 5, wherein the thickness of said secondary thick oxide is between 500 nm to 1000 nm.

8. A method of manufacturing precision chip capacitor as recited in claim 5, wherein the thickness of said main thin oxide is between 10 nm to 300 nm.
